(19) United States
(12) Patent Application Publication
(10) Pub. No.: US 2010/0035166 A1
(43) Pub. Date: Feb. 11, 2010

(54) PHOTOSENSITIVE COMPOSITION, PARTITION WALLS, BLACK MATRIX AND PROCESS FOR PRODUCING COLOR FILTER

(75) Inventors: Kenji Ishizeki, Chiyoda-ku (JP); Kazushi Kobayashi, Chiyoda-ku (JP); Hideyuki Takahashi, Chiyoda-ku (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Asahi Glass Company, Limited, Tokyo (JP)

(21) Appl. No.: 12/578,625

(22) Filed: Oct. 14, 2009

Related U.S. Application Data
(63) Continuation of application No. PCT/JP08/57982, filed on Apr. 24, 2008.

(30) Foreign Application Priority Data
Apr. 25, 2007 (JP) 2007-115726

(51) Int. Cl. G03F 1/00; G03F 7/004; G03F 7/20

(52) U.S. Cl. 430/7; 430/287.1; 430/325; 430/319

(57) ABSTRACT

To provide a photosensitive composition with which partition walls (black matrix) having high sensitivity to light and being excellent in liquid repellency, and pixels excellent in the uniformity in the ink layer thickness, can be formed.

A photosensitive composition, which comprises a fluoropolymer (A) having a side chain containing a group such as —(CF₂)₆F and a side chain containing an ethylenic double bond in one molecule, an alkali soluble photosensitive resin (B), a photopolymerization initiator (C), a black pigment (D), a polymer dispersing agent (E) having basic functional groups, and fine particles (F) other than the black pigment (D).

### TECHNICAL FIELD

The present invention relates to a black matrix to be used for formation of a color filter and an organic EL display device employing an ink jet printing technique, and a photosensitive composition to be used for formation of the black matrix.

### BACKGROUND ART

In recent years, a low cost process utilizing an ink jet printing technique has been proposed as a process for producing a color filter or an organic EL display device.

For example, in production of a color filter, partition walls as a black matrix are formed by photolithography, and then open areas (dots) surrounded by the partition walls are sprayed and coated with inks of R (red), G (green) and B (blue) by an ink jet method to form pixels.

In production of an organic EL display device, partition walls as a black matrix are formed by photolithography, and then open areas (dots) surrounded by the partition walls are sprayed and coated with solutions of a hole transport material and a luminescent material by an ink jet method to form pixels having a hole transport layer, a luminescent layer, etc.

In the ink jet method, it is necessary to prevent color mixing of inks between adjacent pixels. Accordingly, the partition walls (black matrix) are required to have a repellency against water, an organic solvent or the like constituting the ink jet coating solution, i.e. a so-called liquid repellency.

Further, in the ink jet method, it is necessary to form pixels excellent in the uniformity in the ink layer thickness. Accordingly, the open areas (dots) surrounded by the partition walls are required to have wettability by an ink constituting the ink jet discharged solution, i.e. a so-called liquid affinity.

Further, for cost reduction and improvement in the productivity, a black matrix forming material is required to have high sensitivity with which patterning is possible with a low exposure dose.

A black matrix comprising partition walls having liquid repellency may be formed by photolithography using a photosensitive composition comprising a fluorinated compound and a black pigment. The photolithography comprises, for example, a step of coating a substrate with a photosensitive composition to form a coating film, a step of drying the coating film, a step of exposing a part of the coating film, a step of removing the non-exposed portion by alkali development, and a postbaking step of finally carrying out heat treatment.

Patent Document 1 discloses formation of a black matrix by photolithography from a photosensitive resin composition comprising a copolymer having fluoroalkyl groups and ethylenic double bonds and a black pigment such as carbon black.

Patent Document 1: WO2004/79454

### DISCLOSURE OF THE INVENTION

### Object to be Accomplished by the Invention

The copolymer having fluoroalkyl groups and ethylenic double bonds disclosed in Patent Document 1, which has fluoroalkyl groups in its side chains, moves to the vicinity of the coating film surface in the drying step. Accordingly, the upper surface of the partition walls formed by the photosensitive composition has liquid repellency. Further, since the composition has side chains having ethylenic double bonds, it is possible to fix it to the surface of the partition walls by curing reaction in the exposure step.

However, the present inventors have found that in a case where a polymer dispersing agent having basic functional groups is used to disperse the black pigment, color mixing between adjacent pixels may occur in some cases by coating with an ink by an ink jet method, that is, the partition walls do not have desired liquid repellency. The reason is not clearly understood, but it is considered that in the postbaking step in photolithography, a bonding moiety to which the fluoroalkyl groups are bonded is decomposed by catalytic activity of the basic functional groups in the polymer dispersing agent.

Further in a case where a dispersing agent other than the polymer dispersing agent having basic functional groups is used as the dispersing agent for the black pigment, the dispersibility of the black pigment tends to be low, whereby sensitivity of the photosensitive composition to light tends to be low or partition walls having a smooth surface is hardly obtained.

Accordingly, it is an object of the present invention to provide a photosensitive composition with which it is possible to form partition walls (black matrix) having high sensitivity to light and being excellent in liquid repellency and to form pixels excellent in the uniformity in the ink layer thickness.

### Means to Accomplish the Object

The present inventors have found that by incorporating fine particles other than a black pigment to a photosensitive composition, partition walls also excellent in liquid repellency can be formed even when a polymer dispersing agent having basic functional groups is used, and accomplished the invention.

That is, the present invention provides the following.

(1) A photosensitive composition, which comprises a fluoropolymer (A) having a side chain containing a group represented by the following formula 1 and a side chain containing an ethylenic double bond in one molecule, an alkali soluble photosensitive resin (B), a photopolymerization initiator (C), a black pigment (D), a polymer dispersing agent (E) having basic functional groups, and fine particles (F) other than the black pigment (D):

—CFXR^{f} formula 1

wherein X is a hydrogen atom, a fluorine atom or a trifluoromethyl group, and RF is an alkyl group having at most 20 carbon atom which may have an etheric oxygen atom, at least one of hydrogen atoms of which is substituted by a fluorine atom, or a fluorine atom.
(2) The photosensitive composition according to the above (1), wherein the proportions of the respective components in the total solid content of the photosensitive composition are such that the fluoropolymer (A) is from 0.1 to 30 mass %, the alkali soluble photosensitive resin (B) is from 5 to 80 mass %, the photopolymerization initiator (C) is from 0.1 to 50 mass %, the black pigment (D) is from 20 to 50 mass %, and the fine particles (F) other than the black pigment (D) are from 3 to 20 mass %, and the proportion of the polymer dispersing agent (E) is from 5 to 30 mass % based on the black pigment (D).
(3) The photosensitive composition according to the above (1) or (2), wherein the fine particles (F) are negatively charged.
(4) The photosensitive composition according to any one of the above (1) to (3), wherein the fluoropolymer (A) has a side chain containing at least two ethylenic double bonds per one side chain.
(5) The photosensitive composition according to any one of the above (1) to (4), wherein the fluoropolymer (A) further has a side chain containing an acidic group.
(6) Partition walls made of a coating film cured product of the photosensitive composition as defined in any one of the above (1) to (5).
(7) A black matrix comprising the partition walls as defined in the above (6).
(8) A process for forming a black matrix, which comprises a step of coating a substrate with the photosensitive, composition as defined in any one of the above (1) to (5) to form a coating film, a step of drying the coating film, an exposure step, a development step and a postbaking step in this order.
(9) A process for forming a color filter, which comprises, after forming a black matrix by the process as defined in the above (8), injecting an ink by an ink jet method within regions partitioned by the black matrix, to form pixels.
(10) A process for forming an organic EL display device, which comprises, after forming a black matrix by the process as defined in the above (8), injecting an ink by an ink jet method within regions partitioned by the black matrix, to form pixels.

To the photosensitive composition of the present invention, the fine particles (F) other than the black pigment (D) (hereinafter simply referred to as fine particles (F)) are added. By adding the fine particles (F), the polymer dispersing agent (E) having basic functional groups are adsorbed and trapped, whereby activity of the polymer dispersing agent having basic functional groups is suppressed. Accordingly, it is considered that in the postbaking step in formation of partition walls, decomposition at a moiety to which a group represented by the formula 1 is connected is suppressed, whereby the decrease in the liquid repellency can be presented. Accordingly, since the partition walls to be formed from the photosensitive composition have high liquid repellency, inks injected by the ink jet method will not flow over the pixels, and color mixing between adjacent pixels will hardly occur.

The fine particles (F) in the present invention are preferably negatively charged, since they are likely to adsorb the polymer dispersing agent (E) having basic functional groups by electric interaction.

In the present invention, the fluoropolymer (A) has an ethylenic double bond in its side chain, and accordingly it is likely to be fixed on the upper surface of the partition walls by the curing reaction of the fluoropolymer (A), whereby staining of dots (open areas, and portions to be pixels) by migration (moving) of unreacted residual molecules to the dots will hardly occur. That is, since the dots will be excellent in liquid affinity, the ink will wetly spread within the dots, and pixels excellent in the uniformity in the ink layer thickness will easily be formed.

In the present invention, the fluoropolymer (A) preferably has a side chain containing at least 2 ethylenic double bonds per one side chain, whereby the fluoropolymer (A) is likely to be fixed on the upper surface of the partition walls.

The fluoropolymer (A) in the present invention preferably has a side chain containing an acidic group. Some molecules of the fluoropolymer (A) not cured in the exposure step will be washed off from the upper surface of the partition walls in the development step, as they have the side chain containing an acidic group, whereby the residual molecules not fixed will scarcely remain in the partition walls. Thus, it is possible to reduce molecules which may otherwise migrate to the dots at a stage prior to the postbaking step, such being more effective for formation of pixels excellent in the uniformity in the ink layer thickness.

### EFFECTS OF THE INVENTION

The photosensitive composition of the present invention has high sensitivity to light, and partition walls (a black matrix) excellent in the liquid repellency and pixels excellent in the uniformity in the ink layer thickness can be formed with it. Accordingly, the color filter and the organic EL display device having the partition walls (black matrix) of the present invention are free from color mixing of inks and are excellent in the uniformity in the ink layer thickness.

### BEST MODE FOR CARRYING OUT THE INVENTION

Now, the present invention will be described in further detail below. In the present specification, “%” means “mass %” unless otherwise specified. Further, a (meth)acryloyl group generically means both acryloyl group and methacryloyl group. A (meth)acrylate generically means both acrylate and methacrylate. (Meth)acrylic acid generically means both acrylic acid and methacrylic acid. Further, (meth)acrylamide generically means both acrylamide and methacrylamide.

The fluoropolymer (A) has a side chain containing a group represented by the following formula 1 and a side chain containing an ethylenic double bond in one molecule:

—CFXR^{f} Formula 1

wherein X is a hydrogen atom, a fluorine atom or a trifluoromethyl group, and R^{f} is an alkyl group having at most 20 carbon atoms which may have an etheric oxygen atom, at least one of hydrogen atoms of which is substituted by a fluorine atom, or a fluorine atom.

The side chain containing a group represented by the formula 1 may be directly formed by a polymerization reaction or may be formed by chemical exchange after the polymerization reaction. Further, a side chain containing an ethylenic double bond can be formed by chemical conversion after the polymerization reaction.

When R^{f} in the above formula 1 is an alkyl group having at most 20 carbon atoms, at least one of hydrogen atoms of which is substituted by a fluorine atom, the hydrogen atoms in the alkyl group may be substituted by a halogen atom other than a fluorine atom, and such a halogen atom is preferably a chlorine atom. Further, the etheric oxygen atom may be present between the carbon-carbon bond in the alkyl group, or may be present at the terminal of the alkyl group. Further, the structure of the alkyl group may be a chain structure, a branched structure, a cyclic structure or a structure partially having a cyclic structure, and is preferably a chain structure.

Specific examples of the group represented by the above formula 1 may, for example, be the following may be mentioned.

—CF₃, —CF₂CF₃, —CF₂CHF₂, —(CF₂)₂CF₃, —(CF₂)₃CF₃, —(CF₂)₄CF₃, —(CF₂)₅CF₃,
—(CF₂)₆CF₃, —(CF₂)₇CF₃, —(CF₂)₈CF₃, —(CF₂)₉CF₃, —(CF₂)₁₁CF₃, —(CF₂)₁₅CF₃,

### —CF(CF₃)O(CF₂)₅CF₃,

—CF₂O(CF₂CF₂O)ₚCF₃ (p is an integer of from 1 to 8),
—CF(CF₃)O(CF₂CF(CF₃)O)_{q}C₆F₁₃ (q is an integer of from 1 to 4), and
—CF(CF₃)O(CF₂CF(CF₃)O)ᵣC₃F₇ (r is an integer of from 1 to 5).

The group represented by the above formula 1 is preferably a perfluoroalkyl group or a polyfluoroalkyl group containing one hydrogen atom, particularly preferably a perfluoroalkyl group (provided that the above alkyl group includes one having an etheric oxygen atom), whereby the partition walls to be formed from the photosensitive composition have good liquid repellency.

Further, the group represented by the above formula 1 preferably has 4 to 6 carbon atoms in total. In such a case, sufficient liquid repellency will be imparted to the partition walls and in addition, the compatibility of the fluoropolymer (A) with other components constituting the photosensitive composition will be good, whereby when the photosensitive composition is applied to form a coating film, the fluoropolymer (A) molecules will not aggregate, and partition walls having good outer appearance will be formed.

The ethylenic double bond may, for example, be an addition-polymerizable unsaturated group such as a (meth)acryloyl group, an allyl group, a vinyl group or a vinyl ether group. Some or all of hydrogen atoms in such a group may be substituted by a hydrocarbon group. The hydrocarbon group is preferably a methyl group.

The fluoropolymer (A) of the present invention can be prepared by copolymerizing at least two monomers including a monomer (a1) containing a group represented by the formula 1 and a monomer (a2) containing a reactive group and then reacting the obtained copolymer with a compound (z1) containing a functional group capable of being bonded to the above reactive group and an ethylenic double bond.

The monomer (a1) having a group represented by the formula 1 is preferably a monomer represented by the following formula 11.

CH₂═CR²COO—Y—CFXR^{f} Formula 11

wherein R² is a hydrogen atom, a fluorine atom, a chlorine atom, a bromine atom, an iodine atom, a methyl group or a trifluoromethyl group, Y is a single bond or a C₁₋₆ bivalent organic group containing no fluorine atom, and R^{f} is an alkyl group having at most 20 carbon atoms which may contain an etheric oxygen atom, at least one of hydrogen atoms of which is substituted by a fluorine atom, or a fluorine atom.

In the above formula 11, the preferred embodiment of —CFXR^{f} is as defined for the above formula 1.

In the above formula 11, Y is preferably a C₂₋₄ alkylene group in view of the availability.

As examples of the monomer represented by the above formula 11, the following may be mentioned.

CH₂═CR²COOR³CFXR^{f}

CH₂═CR²COOR³NR⁴SO₂CFXR^{f}

CH₂═CR²COOR³NR⁴COCFXR^{f}

CH₂═CR²COOCH₂CH(OH)R⁵CFXR^{f}

In the above formulae, R² is a hydrogen atom, a fluorine atom, a chlorine atom, a bromine atom, an iodine atom, a methyl group or a trifluoromethyl group, R³ is a C₁₋₄ alkylene group, R⁴ is a hydrogen atom or a methyl group, R⁵ is a single bond or a C₁₋₄ alkylene group, and R^{f} is as defined above.

Specific examples of R³ may, for example, be —CH₂—, —CH₂CH₂—, —CH(CH₃)—, —CH₂CH₂CH₂—, —(C(CH₃)₂—, —CH(CH₂CH₃)—, —CH₂ CH₂CH₂CH₂—, —CH(CH₂CH₂CH₃)—, —CH₂(CH₂)₃CH₂— and —CH(CH₂CH(CH₃)₂)— may be mentioned.

Specific examples of R⁵ may, for example, be —CH₂—, —CH₂CH₂—, —CH(CH₃)—, —CH₂CH₂CH₂—, —(C(CH₃)₂—, —CH(CH₂CH₃)—, —CH₂ CH₂CH₂CH₂— and —CH(CH₂CH₂CH₃)— may be mentioned.

Specific; examples of the monomer represented by the above formula 11 may, for example, be 2-(perfluorohexyl)ethyl(meth)acrylate and 2-(perfluorobutyl)ethyl(meth)acrylate may be mentioned. The monomers represented by the formula 11 may be used alone or in combination as a mixture of two or more of them.

The monomer (a2) containing a reactive group may, for example, be a monomer containing a hydroxy group, an acid anhydride monomer containing an ethylenic double bond, a monomer containing a carboxy group or a monomer containing an epoxy group. Here, the monomer (a2) preferably contains substantially no group represented by the formula 1.

After the copolymerization, the reactive group of the monomer (a2) will be reacted with a compound (z1) containing a functional group capable of being bonded to the above reactive group and an ethylenic double bond, to form a fluoropolymer (A) having a side chain containing an ethylenic double bond.

Specific examples of the monomer containing a hydroxy group may, for example, be 2-hydroxyethyl(meth)acrylate, 2-hydroxypropyl(meth)acrylate, 3-hydroxypropyl(meth)acrylate, 4-hydroxybutyl(meth)acrylate, 5-hydroxypentyl(meth)acrylate, 6-hydroxyhexyl(meth)acrylate, 4-hydroxycyclohexyl(meth)acrylate, neopentyl glycol mono(meth)acrylate, 3-chloro-2-hydroxypropyl (meth)acrylate, glycerol mono(meth)acrylate, 2-hydroxyethyl vinyl ether, 4-hydroxybutyl vinyl ether, cyclohexanediol monovinyl ether, 2-hydroxyethyl allyl ether, N-hydroxymethyl(meth)acrylamide and N,N-bis(hydroxymethyl)(meth)acrylamide.

Further, the monomer containing a hydroxy group may be a monomer having a polyoxyalkylene chain with a terminal hydroxy group. It may, for example, be CH₂═CHOCH₂C₆H₁₀CH₂O(C₂H₄O)ₖH (wherein k is an integer of from 1 to 100, the same applies hereinafter), CH₂═CHOC₄HBO(C₂H₄O)ₖH, CH₂═CHCOOC₂H₄O(C₂H₄O)ₖH, CH₂═C(CH₃)COOC₂H₄O(C₂H₄O)ₖH or CH₂═CHCOOC₂H₄O(C₂H₄O)ₘ(C₃H₆O)ⱼH (wherein m is 0 or an integer of from 1 to 100, and j is an integer of from 1 to 100, provided that m+j is from 1 to 100, the same applies hereinafter), or CH₂═C(CH₃)COOC₂H₄O(C₂H₄O)ₘ(C₃H₆O)ⱼH.

Specific examples of the acid anhydride monomer having an ethylenic double bond may, for example, be maleic anhydride, itaconic anhydride, citraconic anhydride, methyl-5-norbornene-2,3-dicarboxylic anhydride, 3,4,5,6-tetrahydrophthalic anhydride, cis-1,2,3,6-tetrahydrophthalic anhydride and 2-buten-1-yl succinic anhydride.

Specific examples of the monomer containing a carboxy group may, for example, be acrylic acid, methacrylic acid, vinyl acetic acid, crotonic acid, itaconic acid, maleic acid, fumaric acid, cinnamic acid and their salts.

Specific examples of the monomer containing an epoxy group may, for example, be glycidyl (meth)acrylate and 3,4-epoxycyclohexylmethyl acrylate.

In the present invention, the fluoropolymer (A) preferably further has a side chain containing an acidic group. Some molecules of the fluoropolymer (A) not cured in the exposure step will be washed off from the surface of the partition walls in the development step, as they have the side chain containing an acidic group, whereby the residual molecules not fixed in the partition walls will scarcely remain. It is thereby possible to further reduce molecules which may otherwise migrate to dots between the partition walls at a stage prior to the post-exposure step, whereby the liquid affinity of the dots will be higher.

As the acidic group, at least one acidic group selected from the group consisting of a carboxy group, a phenolic hydroxy group and a sulfonic acid group is preferred.

The side chain containing an acid group may be formed by the polymerization reaction of the monomer (a3) containing an acidic group or may be formed by a chemical conversion after the polymerization reaction.

In a case where a monomer containing a carboxy group is used as the monomer (a3) containing an acidic group, and a monomer containing a carboxy group is used also as the above-mentioned monomer (a2) having a reactive group, one having no ethylenic double bond finally introduced and having a residual carboxy group, will be regarded as the monomer (a3).

The monomer containing a phenolic hydroxy group may, for example, be o-hydroxystyrene, m-hydroxystyrene or p-hydroxystyrene. Or, it may be a monomer having at least one hydrogen atom in such a benzene ring substituted by an alkyl group such as a methyl group, an ethyl group or a n-butyl group; an alkoxy group such as a methoxy group, an ethoxy group or a n-butoxy group; a halogen atom a haloalkyl group having at lease one hydrogen atom of an alkyl group substituted by a halogen atom; a nitro group; a cyano group; or an amide group.

The monomer containing a sulfonic acid group may, for example, be vinyl sulfonic acid, styrene sulfonic acid, (meth)allyl sulfonic acid, 2-hydroxy-3-(meth)allyloxypropane sulfonic acid, 2-sulfoethyl(meth)acrylate, 2-sulfopropyl(meth)acrylate, 2-hydroxy-3-(meth)acryloxypropane sulfonic acid, or 2-(meth)acrylamide-2-methylpropane sulfonic acid.

In the process for producing the copolymer of the present invention, the monomer to be used for the polymerization may contain a monomer (a4) other than the monomer (a1) containing a group represented by the formula 1, the monomer (a2) containing a reactive group and the monomer (a3) containing an acidic group.

Such other monomer (a4) may, for example, be a hydrocarbon type olefin, a vinyl ether, an isopropenyl ether, an allyl ether, a vinyl ester, an allyl ester, a (meth)acrylate, a (meth)acrylamide, an aromatic vinyl compound, a chloroolefin or a conjugated diene. Such a monomer (a4) may contain a functional group, and the functional group may, for example, be a carbonyl group or an alkoxy group. A (meth)acrylate or a (meth)acrylamide is particularly preferred, since the heat resistance of the partition walls will thereby be excellent.

Further, a (meth)acrylate containing a silicone group may be copolymerized. For example, CH₂═CR⁶COO—CH₂CH₂CH₂—(SiR⁷R⁸O)ₙ—(SiR⁷R⁸R⁹) may be mentioned, wherein R⁶ is a hydrogen atom or a methyl group, each of R⁷ and R⁸ which are independent of each other, is a hydrogen atom, an alkyl group, a cycloalkyl group or an aryl group, R⁹ is a hydrogen atom or a C₁₋₁₀ organic group, and n is an integer of from 1 to 200.

The fluoropolymer (A) may be prepared, for example, by the following method. Firstly, the monomer is dissolved in a solvent and heated, and a polymerization initiator is added to carry out copolymerization. In the copolymerization reaction, a chain transfer agent may preferably be present, as the case requires. The monomer, the polymerization initiator, the solvent and the chain transfer agent may continuously be added.

The above solvent may, for example, be an alcohol such as ethanol, 1-propanol, 2-propanol, 1-butanol or ethylene glycol; a ketone such as acetone, methyl isobutyl ketone or cyclohexanone; a cellosolve such as 2-methoxyethanol, 2-ethoxyethanol or 2-butoxyethanol; a carbitol such as 2-(2-methoxyethoxy)ethanol, 2-(2-ethoxyethoxy)ethanol or 2-(2-butoxyethoxy)ethanol; an ester such as methyl acetate, ethyl acetate, n-butyl acetate, ethyl lactate, n-butyl lactate, ethylene glycol monomethyl ether acetate, propylene glycol monomethyl ether acetate, ethylene glycol diacetate or glycerol triacetate; diethylene glycol dimethyl ether or diethylene glycol methylethyl ether.

As the polymerization initiator, a known organic peroxide, an inorganic peroxide, or an azo compound may, for example, be mentioned. The organic peroxide and the inorganic peroxide may be used in combination with a reducing agent in the form of a redox catalyst.

The organic peroxide may, for example, be benzoyl peroxide, lauroyl peroxide, isobutyl peroxide, t-butyl hydroperoxide or t-butyl-α-cumyl peroxide.

The inorganic peroxide may, for example, be ammonium persulfate, sodium persulfate, potassium persulfate, hydrogen peroxide or a percarbonate.

The azo compound may, for example, be 2,2′-azobisisobutyronitrile, 1,1′-azobis(cyclohexane-1-carbonitrile), 2,2′-azobis(2,4-dimethylvaleronitrile), 2,2′-azobis(4-methoxy-2,4-dimethylvaleronitrile), dimethyl 2,2′-azobisisobutyrate or 2,2′-azobis(2-amidinopropane)dihydrochloride.

The chain transfer agent may, for example, be a mercaptan such as n-butylmercaptan, n-dodecylmercaptan, t-butylmercaptan, ethyl thioglycolate, 2-ethylhexyl thioglycolate or 2-mercaptoethanol; or an alkyl halide such as chloroform, carbon tetrachloride or carbon tetrabromide.

The copolymer obtained as described above is reacted with a compound (z1) having a functional group capable of being bonded with the reactive group and an ethylenic double bond to obtain the fluoropolymer (A).

The following combinations may, for example, be mentioned as a combination of a reactive group to the compound (z1) containing a functional group capable of being bonded with the reactive group and an ethylenic double bond.

(1) A hydroxy group to an acid anhydride containing an ethylenic double bond.

(2) A hydroxy group to a compound containing an isocyanate group and an ethylenic double bond.

(3) A hydroxy group to a compound containing a chlorinated acyl group and an ethylenic double bond.

(4) An acid anhydride to a compound containing a hydroxy group and an ethylenic double bond.

(5) A carboxy group to a compound containing an epoxy group and an ethylenic double bond.

(6) An epoxy group to a compound (z1) containing a carboxy group and an ethylenic double bond.

As specific examples of the acid anhydride containing an ethylenic double bond, the above-mentioned examples may be mentioned.

As specific examples for the compound containing an isocyanate group and an ethylenic double bond, (meth)acryloyloxyethyl isocyanate and 1,1-(bis(meth)acryloyloxymethyl)ethyl isocyanate may be mentioned.

As a specific example for the compound containing a chlorinated acyl group and an ethylenic double bond, (meth)acryloyl chloride may be mentioned.

As specific examples for the compound containing a hydroxy group and an ethylenic double bond, the above-mentioned examples for the monomer containing a hydroxy group may be mentioned.

As specific examples for the compound containing an epoxy group and an ethylenic double bond, the above-mentioned examples for the monomer containing an epoxy group may be mentioned.

As specific examples for the compound containing a carboxy group and an ethylenic double bond, the above-mentioned examples for the monomer containing a carboxy group may be mentioned.

As the above combination, particularly preferred is a combination of a hydroxy group to 1,1-((bis(meth)acryloyloxymethyl)ethyl isocyanate, whereby the fluoropolymer (A) has a side chain containing at least 2 ethylenic double bonds per one side chain, and the fluoropolymer (A) thereby has excellent fixing property to the surface of partition walls.

When the copolymer is reacted with the compound (z1) containing a functional group capable of being bonded to the reactive group and an ethylenic double bond, the solvent exemplified in the above-described preparation of the copolymer may be used as the solvent to be used for the reaction.

Further, a polymerization inhibitor may preferably be blended. The polymerization inhibitor may, for example, be 2,6-di-t-butyl-p-cresol.

Further, a catalyst or a neutralizing agent may be added. For example, in a case where a copolymer having a hydroxy group is to be reacted with a compound containing an isocyanate group and an ethylenic double bond, a tin compound or the like may be used. In a case where a copolymer containing a hydroxy group is to be reacted with a compound containing a chlorinated acyl group and an ethylenic double bond, a basic catalyst may be used.

The preferred proportion of each monomer based on the total mass of monomers to be copolymerized is as follows. The proportion of the monomer (a1) containing a group represented by the formula is preferably from 20 to 80 mass %, more preferably from 30 to 60 mass %. As the proportion is high, the fluoropolymer (A) of the present invention will be excellent in the effect to lower the surface tension of the partition walls made of a coating film cured product to be formed, and a high liquid repellency will be imparted to the partition walls. On the other hand, if the proportion is too high, the adhesion between the partition walls and the substrate tends to be low.

The proportion of the monomer (a2) containing a reactive group is preferably from 20 to 70 mass %, more preferably from 30 to 50 mass %. Within such a range, the fluoropolymer (A) will have good developability and fixing property to partition walls.

The proportion of the monomer (a3) having an acidic group is preferably from 2 to 20 mass %, more preferably from 4 to 12 mass %. Within such a range, the residual molecules not fixed in the exposure step will be readily washed off from the partition walls in the development step.

The proportion of other monomer (a4) is preferably at most 70 mass %, more preferably at most 50 mass %. Further, the lower limit is 1 mass %. When the proportion is within such a range, the alkali solubility and the developability will be good.

It is preferred that the copolymer and the compound (z1) are charged so that the equivalent ratio of [functional group of the compound (z1)]/[reactive group of the copolymer] would be from 0.5 to 2.0. As the equivalent ratio is high, the fluoropolymer (A) will have good fixing property to partition walls. On the other hand, if the equivalent ratio is too high, an impurity as an unreacted compound (z1) increases, whereby the appearance of a coating film will be deteriorated. The equivalent ratio is more preferably from 0.8 to 1.5. Further, in a case where a monomer having a carboxy group is used for both of the monomer (a2) having a reactive group and the monomer (a3) having an acidic group, the amounts of the copolymer and the compound (z1) to be charged may be adjusted so that the acid value of the fluoropolymer (A) is an aimed value.

The content of fluorine atoms of the fluoropolymer (A) is preferably from 5 to 35 mass %. The higher the content, the more the fluoropolymer (A) will be excellent in the effect to lower the surface tension of the partition walls, and the higher the liquid repellency to be imparted to the partition walls. On the other hand, if the content is too high, the adhesion between the partition walls and the substrate tends to be low. The content of fluorine atoms of the fluoropolymer (A) is more preferably such that the lower limit is 10 mass %, and the upper limit is 30 mass %.

The fluoropolymer (A) preferably has at least 2 and at most 100, more preferably at least 6 and at most 50 ethylenic double bonds in its molecule. Within such a range, the fluoropolymer (A) will have good developability and fixing property to partition walls.

The acid value of the fluoropolymer (A) is preferably at most 100 mgKOH/g, more preferably from 10 to 50 mgKOH/g. Within such a range, the residual molecules not fixed in the exposure step will be readily washed off from the partition walls in the development step. Here, the acid value is the mass (unit: mg) of potassium hydroxide required to neutralize 1 g of the resin, and in this specification, the unit is identified by mgKOH/g.

The weight average molecular weight of the fluoropolymer (A) is preferably at least 500 and less than 15,000, more preferably at least 1,000 and less than 10,000. Within such a range, the alkali solubility and the developability are good.

The proportion of the fluoropolymer (A) in the total solid content of the photosensitive composition of the present invention is preferably from 0.1 to 30 mass %. When such a proportion is high, the fluoropolymer (A) will be excellent in the effect to lower the surface tension of the partition walls to be formed, and a high liquid repellency will be imparted to the partition walls. On the other hand, if the proportion is too high, the adhesion between the partition walls and the substrate tends to be low. The proportion of the fluoropolymer (A) in the total solid content of the composition is more preferably such that the lower limit is 0.15 mass % and the upper limit is 20 mass %.

In the present invention, the alkali soluble photosensitive resin (B) is photosensitive, and undergoes photocuring to be converted to an alkali-insoluble resin. Such an alkali soluble photosensitive resin (B) may, for example, be a vinyl polymer (B-1) having a side chain containing an ethylenic double bond and a side chain containing an acidic group, or a resin (B-2) having an ethylenic double bond and an acidic group introduced to an epoxy resin. In this specification, in a case where a vinyl polymer having a side chain containing an ethylenic double bond and a side chain containing an acidic group has a side chain containing a group represented by the above formula 1, such a vinyl polymer is regarded as the fluoropolymer (A), not the vinyl polymer (B-1).

The above vinyl polymer (B-1) can be prepared in the same manner as in the preparation of the fluoropolymer (A) except that the monomer (a1) containing a group represented by the formula 1 is not used.

The epoxy resin to be used for preparation of the resin (B-2) may, for example, be a bisphenol A type epoxy resin, a bisphenol F type epoxy resin, a phenol novolac type epoxy resin, a cresol novolac type epoxy resin, a trisphenolmethane type epoxy resin, an epoxy resin having a naphthalene skeleton, an epoxy resin having a biphenyl skeleton represented by the following formula 2 (provided that s is from 2 to 50) or an epoxy resin represented by the following formula 3 (provided that each of R⁷, R⁸, R⁹ and R¹⁰ which are independent of one another is a hydrogen atom, a chlorine atom or a C₁₋₅ alkyl group, and t is from 0 to 10).

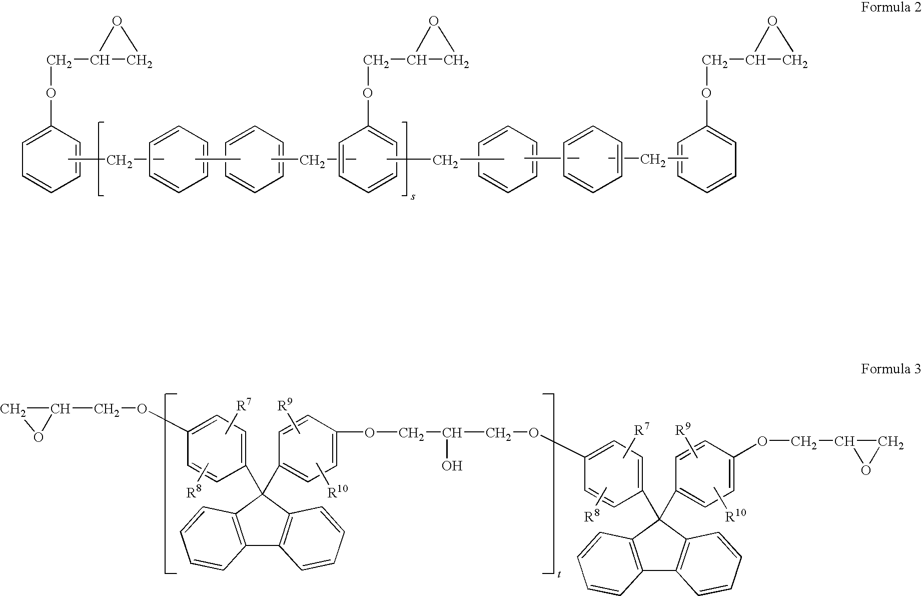

An ethylenic double bond is introduced to an epoxy resin by reacting a compound having a carboxy group and an ethylenic double bond with the epoxy resin. Further, by reacting an acid anhydride therewith, it is possible to introduce the carboxy group as an acidic group. Especially, in a case where the compound having a carboxy group and an ethylenic double bond is reacted with the epoxy resin represented by the above formula 3, and then an acid anhydride is reacted therewith, it is preferred to react a mixture of dicarboxylic anhydride and tetracarboxylic dianhydride. It is thereby possible to control a molecular weight by changing the ratio of dicarboxylic anhydride and tetracarboxylic dianhydride.

Commercial products of the resin (B-2) having an ethylenic double bond and an acidic group introduced to the epoxy resin may, for example, be KAYARAD PCR-1069, K48C, CCR-1105, CCR-1115, CCR-1163H, CCR-1166H, CCR-1159H, TCR-1025, TCR-1064, TCR-1286, ZAR-1535, ZFR-1122, ZFR-1124, ZFR-1185, ZFR-1492H, ZCR-1571H, ZCR1569H, ZCR-1580H, ZCR1581H and ZCR1588H (all manufactured by Nippon Kayaku Co., Ltd.).

The acid value of the alkali soluble photosensitive resin (B) is preferably from 10 to 300 mgKOH/g, more preferably from 30 to 150 mgKOH/g. Within such a range, the alkali solubility and the developability of the photosensitive composition will be good.

The alkali soluble photosensitive resin (B) preferably has at least three ethylenic double bonds in one molecule, preferably at least 6 ethylenic double bonds in one molecule. It is thereby possible that the difference in alkali solubility may readily be made between an exposed portion and a non-exposed portion, and it becomes possible to form a fine pattern with a lower exposure dose.

The weight average molecular weight of the alkali soluble photosensitive resin (B) is preferably at least 500 and less than 200,000, more preferably at least 800 and less than 15,000. Within such a range, the alkali solubility and the developability of the photosensitive composition will be good.

The alkali soluble photosensitive resin (B) preferably further has a carboxy group or a hydroxy group as a crosslinkable group. In a case where the photosensitive composition of the present invention further contains a thermosetting agent (H) which is a compound having at least two groups capable of reacting with a carboxy group or a hydroxy group, such a thermosetting resin undergoes a crosslinking reaction with the alkali soluble photosensitive resin (B) by heat treatment after the development, whereby the crosslinked density of the partition walls will increase, and the heat resistance will be improved. The carboxy group or the phenolic hydroxy group as an acidic group is also a crosslinkable group. In a case where the alkali soluble photosensitive resin (B) has a sulfonic acid group or a phosphoric acid group, as an acidic group, it preferably has at least one group selected from the group consisting of a carboxy group, a phenolic hydroxy group and an alcoholic hydroxy group, as a crosslinkable group.

The proportion of the alkali soluble photosensitive resin (B) in the total solid content in the photosensitive composition of the present invention is preferably from 5 to 80 mass %, more preferably from 10 to 60 mass %. Within such a range, the alkali developability of the photosensitive composition will be good.

The photopolymerization initiator (C) preferably contains a compound which emits radicals by light.

The photopolymerization initiator (C) may, for example, be an α-diketone such as benzyl, diacetyl, methylphenylglyoxylate or 9,10-phenanthrenequinone; an acyloin such as benzoin; an acyloin ether such as benzoin methyl ether, benzoin ethyl ether or benzoin isopropyl ether; a thioxanthone such as thioxanthone, 2-chlorothioxanthone, 2-methylthioxanthone, 2,4-dimethylthioxanthone, isopropylthioxanthone, 2,4-diethylthioxanthone, 2,4-dichlorothioxanthone, 2,4-diisopropylthioxanthone or thioxanthone-4-sulfonic acid; a benzophenone such as benzophenone, 4,4′-bis(dimethylamino)benzophenone or 4,4′-bis(diethylamino)benzophenone; an acetophenone such as acetophenone, 2-(4-toluenesulfonyloxy)-2-phenylacetophenone, p-dimethylaminoacetophenone, 2,2′-dimethoxy-2-phenylacetophenone, p-methoxyacetophenone, 2-methyl-[4-(methylthio)phenyl]-2-morpholino-1-propanone or 2-benzyl-2-dimethylamino-1-(4-morpholinophenyl)-butan-1-on; a quinone such as anthraquinone, 2-ethylanthraquinone, camphorquinone or 1,4-naphthoquinone; an aminobenzoate such as ethyl 2-dimethylaminobenzoate, ethyl 4-dimethylaminobenzoate, (n-butoxy)ethyl 4-dimethylaminobenzoate, isoamyl 4-dimethylaminobenzoate or 2-ethylhexyl 4-dimethylaminobenzoate; a halogen compound such as phenacyl chloride or trihalomethyl phenyl sulfone; an acylphosphineoxide; a peroxide such as di-t-butylperoxide; or an oxime ester such as 1,2-octanedione, 1-[4-(phenylthio)-, 2-(o-benzoyloxime) or ethanone 1-[9-ethyl-6-(2-methylbenzoyl)-9H-carbazoyl-3-yl]-1-(o-acetyloxime).

Such photopolymerization initiators may be used alone or in combination as a mixture of two or more of them. Particularly, the above-mentioned aminobenzoate, the above-mentioned benzophenone or the like may be used together with another photoradical-forming agent to exhibit a sensitizing effect. Further, an aliphatic amine such as triethanolamine, methyldiethanolamine, triisopropanolamine, n-butylamine, N-methyldiethanolamine or diethylaminoethyl methacrylate may likewise be used together with a photoradical-forming agent to exhibit a sensitizing effect.

The proportion of the photopolymerization initiator (C) in the total solid content in the photosensitive composition of the present invention is preferably from 0.1 to 50 mass %, more preferably from 0.5 to 30 mass %. Within such a range, the sensitivity of the photosensitive composition will be good.

As the black pigment, it is possible to use, for example, carbon black, aniline black, anthraquinone black pigment or perylene black pigment, e.g. specifically, C.I. Pigment Black 1, 6, 7, 12, 20 or 31. It is also possible to use a mixture of organic or inorganic pigments of e.g. red, blue and green pigments.

As the black pigment (D), carbon black is preferred from the viewpoint of the price and good shielding property. Such carbon black may be surface-treated with e.g. a resin. Further, in order to adjust the color tone, a blue pigment or a purple pigment may be used in combination.

The carbon black is preferably one having a specific surface area of from 50 to 200 m²/g, more preferably from 60 to 110 m²/g as measured by BET method. If carbon black having a specific surface area of less than 50 m²/g is used, the coloring power of the partition walls (black matrix) tends to decrease, and it is thereby necessary to blend a large amount of carbon black in order to obtain desired shielding property, and if carbon black having a specific surface area exceeding 200 m²/g is used, a dispersion aid is likely to be excessively adsorbed on the carbon black, whereby it will be required to incorporate a large amount of a dispersion aid in order to obtain various physical properties. The dispersion aid will be described hereinafter.

Further, the carbon black is preferably one having dibutyl phthalate oil absorption of at most 120 cc/100 g, more preferably at most 100 cc/100 g from the viewpoint of the sensitivity to light. The smaller the oil absorption, the better.

Further, the average particle size of carbon black by a laser diffraction scattering method is preferably such that the lower limit is at least 40 nm, and the upper limit is at most 200 nm, and the average particle size is more preferably within a range of from 60 to 150 nm. If the average particle size is too small, dispersion at a high concentration tends to be difficult, and accordingly, a photosensitive composition having good stability with time will hardly be obtained. If the average particle size is too large, the linearity of the pattern may be deteriorated.

The proportion of the black pigment (D) in the total solid content of the photosensitive composition of the present invention is preferably from 20 to 50 mass %, more preferably from 30 to 40 mass %. If the content is low, no desired light shielding properties will be obtained, and if it is high, the sensitivity or the resolution may be decreased. Thus, the above range is preferred.

The polymer dispersing agent (E) having basic functional groups preferably has, as basic functional groups, primary, secondary or tertiary amino groups, or nitrogen-containing heterocyclic groups such as pyridine, pyrimidine or pyrazine, in view of excellent affinity to the black pigment (D). The polymer dispersing agent (E) is particularly excellent in dispersibility when it has primary, secondary or tertiary amino groups among them. Further, the amine value of the polymer dispersing agent (E) is preferably from 1 to 100 mgKOH/g, more preferably from 2 to 90 mgKOH/g. The amine value is a value obtained by carrying out acid-base titration of amino groups with an acid, represented by the number of milligrams of KOH corresponding to the acid value. If the amine value is low, the dispersion performance tends to decrease, and if the amine value is too high, the developability tends to decrease.

The polymer compound may, for example, be a urethane compound, a polyimide compound, an alkyd compound, an epoxy compound, a polyester compound, a melamine compound, a phenol compound, an acrylic compound, a polyether compound, a vinyl chloride compound, a vinyl chloride/vinyl acetate copolymer compound, a polyamide compound or a polycarbonate compound. Among them, a urethane compound or a polyester compound is particularly preferred. Further, it may contain polymerized units derived from ethylene oxide or propylene oxide in its molecule.

Commercial products of the polymer dispersing agent (E) having basic functional groups may, for example, be DISPARLON DA-7301 manufactured by Kusumoto Chemicals, Ltd., BYK161, BYK162, BYK163 and BYK182 manufactured by BYK-Chemie, and Solsperse 5000 and Solsperse 17000 manufactured by Zeneca Pigments & Additives.

The amount of addition of the polymer dispersing agent (E) having basic functional groups is preferably from 5 to 30 wt %, more preferably from 10 to 25 wt % based on the black pigment (D). If the addition amount is too small, the dispersion performance tends to decrease, and if the addition amount is too large, the developability tends to decrease.

As the case requires, a phthalocyanine pigment derivative or a metal phthalocyanine sulfonamide compound may be used as a dispersion aid in combination. The dispersion aid is considered to be electrically and chemically adsorbed in the black pigment (D) and the polymer dispersing agent (E) and to have a function to improve the dispersion stability.

As the fine particles (F), various inorganic fine particles and organic fine particles may be used, and they are preferably transparent fine particles. The fine particles (F) are preferably ones not having absorption at the wavelength of light to be applied in the exposure step, so as not to decrease the sensitivity of the photosensitive composition, particularly preferably ones not having absorption to i-line (365 nm), h-line (405 nm) and g-line (436 nm) which are dominant wavelengths of an ultrahigh pressure mercury lamp. Further, the fine particles (F) are preferably negatively charged, in view of high performance to adsorb the polymer dispersing agent (E) having basic functional groups.

The average particle size of the fine particles (F) by a laser diffraction scattering method is preferably at most 1 μm, more preferably at most 200 nm, in view of the surface smoothness of the partition walls to be formed. The lower limit of the average particle size of the fine particles (F) is 5 nm.

The inorganic fine particles may, for example, be silica, zirconia, magnesium fluoride, ITO (indium tin oxide) or ATO (antimony tin oxide). The organic fine particles may, for example, be polyethylene or PMMA. From the viewpoint of heat resistance, inorganic fine particles are preferred, and from the viewpoint of the availability and the dispersion stability, silica or zirconia is more preferred.

The proportion of the fine particles (F) in the total solid content in the photosensitive composition of the present invention is preferably from 3 to 20 mass %, more preferably from 5 to 15 mass %, particularly preferably at least 7 mass % and less than 10 mass %. If the content is too low, the effect of suppressing a decrease in the liquid repellency of the partition walls in the postbaking step tends to be low, and if the content is too high, the stability of the liquid of the composition tends to decrease.

In the present invention, the photosensitive composition preferably further contains a radical crosslinking agent (G), whereby curing of the photosensitive composition by irradiation with light will be accelerated, and curing will be possible in a relatively short time. As the radical crosslinking agent (G), a compound is preferred which is insoluble in alkali and contains at least two ethylenic double bonds.

Specific examples of the radical crosslinking agent (G) may, for example, be diethylene glycol di(meth)acrylate, tetraethylene glycol di(meth)acrylate, tripropylene glycol di(meth)acrylate, neopentyl glycol di(meth)acrylate, 1,9-nonanediol di(meth)acrylate, trimethylolpropane tri(meth)acrylate, pentaerythritol tri(meth)acrylate, pentaerythritol tetra(meth)acrylate, ditrimethylolpropane tetra(meth)acrylate, dipentaerythritol hexa(meth)acrylate and urethane (meth)acrylate. They may be used alone or in combination as a mixture of two or more of them.

The proportion of the radical crosslinking agent (G) in the total solid content in the photosensitive composition of the present invention, is preferably from 10 to 60 mass %, more preferably from 15 to 50 mass %. Within such a range, the alkali developability of the photosensitive composition will be good.

In the present invention, the photosensitive composition preferably contains a thermosetting agent (H), as the case requires. It is thereby possible to improve the heat resistance and water permeation resistance of the partition walls.

The thermosetting agent (H) may, for example, be an amino resin, a compound having at least two epoxy groups, a compound having at least two hydrazino groups, a polycarbodiimide compound, a compound having at least two oxazoline groups, a compound having at least two aziridine groups, a polyvalent metal, a compound having at least two mercapto groups or a polyisocyanate compound. An amino resin, a compound having at least two epoxy groups or a compound having at least two oxazoline groups is particularly preferred, whereby chemical resistance of the formed partition walls will be improved.

The proportion of the thermosetting agent (H) in the total solid content in the photosensitive composition of the present invention is preferably from 1 to 50 mass %, more preferably from 5 to 30 mass %. Within such a range, the alkali developability of the photosensitive composition will be good.

The photosensitive composition of the present invention preferably contains a silane coupling agent (I) as the case requires, whereby it is possible to improve the adhesion of the partition walls to the substrate.

Specific examples of the silane coupling agent (I) may, for example, be tetraethoxysilane, 3-glycidoxypropyltrimethoxysilane, methyltrimethoxysilane, vinyltrimethoxysilane, 3-methacryloyloxypropyltrimethoxysilane, 3-chloropropyltrimethoxysilane, 3-mercaptopropyltrimethoxysilane, heptadecafluorooctylethyltrimethoxysilane, N-phenyl-3-aminopropyltrimethoxysilane, a polyoxyalkylene chain-containing triethoxysilane and imidazole silane. They may be used alone or in combination as a mixture of two or more of them.

To the photosensitive composition of the present invention, a curing accelerator, a thickener, a plasticizer, a defoaming agent, a leveling agent, an anti-repellent, an ultraviolet absorber, etc. may be incorporated, as the case requires.

The photosensitive composition of the present invention is preferably applied on a substrate after a diluting agent is added thereto.

As the diluting agent, various monomers exemplified in the description of the fluoropolymer (A) may be used as a reactive diluting agent. Further, solvents exemplified in the description of the solvent to be used for the preparation of the fluoropolymer (A) may be used. As other examples, a linear hydrocarbon such as n-butane or n-hexane, a cyclic saturated hydrocarbon such as cyclohexane, or an aromatic hydrocarbon such as toluene, xylene or benzyl alcohol may, for example, be mentioned. They may be used alone or in combination as a mixture of two or more of them.

Further, the photosensitive composition of the present invention may contain a copolymer made of at least two monomers each having an ethylenic double bond, which is a silicon-containing polymer having a side chain containing a silicone group represented by the following formula 4 and a side chain containing an ethylenic double bond. By containing the silicon-containing polymer, it is possible to improve ink falling property from partition walls.

—(SiR⁷R⁸O)ₙ—SiR⁷R⁸R⁹ Formula 4

wherein each of R⁷ and R⁸ which are independent of each other, is a hydrogen atom, an alkyl group, a cycloalkyl group or an aryl group, R⁹ is a hydrogen atom or a C₁₋₁₀ organic group, and n is an integer of from 1 to 200. As specific examples of the above silicon-containing polymer, the resin (A3-1), the resin (A3-2) and the resin (A3-3) described in Table 2 on page 38 in WO2004/079454 pamphlet may be mentioned.

Now, a photolithography process using the photosensitive composition of the present invention will be mentioned.

### (Coating Film Forming Step)

Firstly, the photosensitive composition of the present invention is applied on a substrate. As the substrate, its material is not particularly limited, but it may, for example, be various types of glass plates; a thermoplastic sheet of e.g. a polyester (such as polyethylene terephthalate), a polyolefin (such as polyethylene or polypropylene), a polycarbonate, a polymethyl methacrylate, a polysulfone, a polyimide or a poly(meth)acryl resin; or a thermosetting plastic sheet of e.g. an epoxy resin or an unsaturated polyester. Especially, from the viewpoint of the heat resistance, a glass plate or a heat resistant plastic such as a polyimide is preferably employed. Further, a transparent substrate is preferred, since the after-mentioned post-exposure is carried out from the rear side on which no partition walls are formed (substrate side).

The coating film-forming method may, for example, be a spin coating method, a spray coating method, a slit coating method, a roll coating method, a rotary coating method or a bar coating method.

The thickness of the coating film varies depending on the material of the substrate and the purpose of use, and is from 0.3 to 300 μm, preferably from 1 to 60 μm.

### (Drying Step)

Then, the coating film is dried. By the drying, the diluting agent will evaporate, whereby a coating film having no adhesion will be obtained. It is preferred to carry out vacuum drying or drying by healing (prebaking). Further, it is more preferred to carry out vacuum drying and drying by heating in combination for efficient drying without non-uniformity in the outer appearance of the coating film. The conditions for the drying vary depending upon the types of the respective components, the blend proportions, etc., and preferably, the vacuum drying can be carried out within wide ranges of from 500 to 10 Pa for from about 10 to about 300 seconds, and the drying by heating is carried out within wide ranges of from 50 to 120° C. for from about 10 to about 2,000 seconds.

### (Exposure Step)

Then, a part of the dried coating film is subjected to exposure. Exposure is preferably carried out via a mask having a predescribed pattern. The light to be irradiated may, for example, be visible light; ultraviolet rays; far ultraviolet rays; an excimer laser such as KrF excimer laser, ArF excimer laser, F₂ excimer laser, Kr₂ excimer laser, KrAr excimer laser or Ar₂ excimer laser; X-rays; or electron beams. Electromagnetic waves having a wavelength of from 100 to 600 nm are preferred, light having a distribution within a range of from 300 to 500 nm is more preferred, and i-line (365 nm), h-line (405 nm) or g-line (436 nm) is particularly preferred.

As an irradiation device, a known ultrahigh pressure mercury lamp or a deep UV lamp may, for example, be used. The exposure dose is preferably within a range of from 5 to 1,000 mJ/cm², more preferably from 50 to 400 mJ/cm². If the exposure dose is too low, curing of partition walls tends to be inadequate, and in the subsequent development, dissolution or peeling is likely to occur. If the exposure dose is too high, it tends to be difficult to obtain a high resolution.

### (Development Step)

After the exposure step, development is carried out by a developer to remove a non-exposed portion. As such a developer, it is possible to employ an aqueous alkali solution containing an alkali such as an inorganic alkali, an amine, an alcoholamine or a quaternary ammonium salt.

The developing time (time during which the coating film is in contact with the developer) is preferably from 5 to 180 seconds. Further, the developing method may be any method such as a paddle method, a dipping method or a shower method. After the development, high pressure washing with water or washing with running water is carried out, followed by drying with compressed air or compressed nitrogen to remove moisture on the substrate.

### (Post-Exposure Step)

Then, post-exposure is preferably carried out as the case requires. The post-exposure may be carried out from either the front side on which partition walls are formed or the rear side (the substrate side) on which no partition walls are formed. Otherwise, the exposure may be carried out from both the front and rear sides. The exposure dose is preferably at least 50 mJ/cm², more preferably at least 200 mJ/cm², furthermore preferably at least 1,000 mJ/cm², particularly preferably at least 2,000 mJ/cm².

As light to be applied, ultraviolet rays are preferred, and as a light source, a known ultrahigh pressure mercury lamp or high pressure mercury lamp may, for example, be used. Such a light source is preferably employed, since it emits light of at most 600 nm which contributes to curing of partition walls, and emission of light of at most 200 nm which causes decomposition by oxidation of partition walls is thereby little. Further, it is preferred to use a quartz tube glass used for a mercury lamp, which has an optical filter function to shield light of at most 200 nm.

Otherwise, a low pressure mercury lamp may also be used as a light source. However, with a low pressure mercury lamp, the emission intensity of wavelength of at most 200 nm is high, and decomposition by oxidation of partition walls is likely to take place by formation of ozone, and accordingly, it is not desirable to carry out a large quantity of exposure. The exposure dose is preferably at most 500 mJ/cm², more preferably at most 300 mJ/cm².

### (Postbaking Step)

Then, it is preferred to heat the partition walls. It is preferred to carry out heat treatment by a heating device such as a hot plate or an oven at from 150 to 250° C. for from 5 to 90 minutes. The heating temperature is more preferably at least 180° C. If the heating temperature is too low, curing of the partition walls tends to be inadequate, whereby no sufficient chemical resistance will be obtained, and accordingly, in a case where they are coated with an ink in the following ink jet coating step, the partition walls may be swelled by the solvent contained in the ink, or the ink may bleed. On the other hand, if the heating temperature is too high, heat decomposition of the partition walls may occur.

By the above-described photolithography process, partition walls (black matrix) can be obtained.

It is possible to use the photosensitive composition of the present invention for pattern formation having a width of partition walls of preferably at most 100 μm, more preferably at most 20 μm in average. Further, it is possible to use the composition for pattern formation having a distance (width of a dot) between adjacent partition walls of preferably at most 300 μm, more preferably at most 100 μm in average. Further, it is possible to use it for pattern formation having a height of partition walls of preferably from 0.05 to 50 μm, more preferably from 0.2 to 10 μm, furthermore preferably from 0.5 to 3 μm in average.

The water-and-oil repellency of a coating film cured product formed from the photosensitive composition of the present invention can be estimated by the contact angle to water and xylene, and the contact angle to water is preferably at least 90°, more preferably at least 95°. Further, the contact angle to xylene is preferably at least 35°, more preferably at least 40°.

### [Formation of Color Filter]

After the black matrix is formed as described above, an ink is injected by an ink jet method within regions partitioned by the black matrix to form pixels, thereby to form a color filter.

The ink jet apparatus to be used for forming such pixels is not particularly limited, and it is possible to use an ink jet apparatus employing various methods, such as a method of continuously jetting an electrified ink and controlling it by a magnetic field, a method of periodically spraying an ink by using piezoelectric elements, a method of heating an ink and intermittently jetting it by utilizing its foaming.

The shape of pixels may be of any known configuration such as a stripe type, a mosaic type, a triangle type or a 4-pixel configuration type.

The ink to be used for forming pixels, mainly comprises a coloring component, a binder resin component and a solvent component. As the coloring component, it is preferred to employ a pigment or dye excellent in heat resistance, light resistance, etc. As the binder resin component, a transparent resin excellent in heat resistance is preferred, such as an acrylic resin, a melamine resin or an urethane resin. A water-base ink comprises, as the solvent, water and, if necessary, a water-soluble organic solvent, and as the binder resin component, a water-soluble resin or a water-dispersible resin, and it contains various additives as the case requires. Whereas, an oil-base ink comprises an organic solvent as the solvent and a resin soluble in the organic solvent as the binder resin component, and it contains various additives as the case requires.

Further, after injecting an ink by an ink jet method, if required, it is preferred to carry out drying, heat-curing or ultraviolet ray-curing.

After forming pixels, an overcoat layer may be formed as the case requires. Such an overcoat layer is formed for the purpose of improving the surface flatness and for the purpose of preventing an eluent from the ink at the black matrix or pixels from reaching to the liquid crystal layer. In a case where such an overcoat layer is to be formed, it is preferred to preliminarily remove the liquid repellency of the black matrix. In a case where the liquid repellency is not removed, the overcoating liquid will be repelled, and a uniform film thickness tends to be hardly obtainable, such being undesirable. The method for removing the liquid repellency of the black matrix may, for example, be plasma ashing treatment or photo ashing treatment.

Further, as the case requires, it is preferred to form a photospacer on the black matrix to improve the product quality of a liquid crystal panel to be produced by using a color filter.

### [Formation of Organic EL Display Device]

After the black matrix is formed as described above, an ink is injected by an ink jet method within regions partitioned by the black matrix to form pixels thereby to form an organic EL display device.

Before the black matrix is formed, a transparent electrode of e.g. indium tin oxide (ITO) is formed by e.g. a sputtering method on a transparent substrate of e.g. glass, and if necessary, the transparent electrode is etched to have a desired pattern. Then, the black matrix of the present invention is formed. Then, by using an ink jet method, solutions of a hole transport material and a luminescent material are sequentially applied within dots and dried to form a hole transport layer and a luminescent layer. Then, an electrode of e.g. aluminum is formed by e.g. a vapor deposition method, whereby pixels for an organic EL display device will be obtained.

### EXAMPLES

Now, the present invention will be described in further detail with reference to Preparation Examples and Examples, but it should be understood that the present invention is by no means thereby restricted.

Further, in the following, “part(s)” and “%” are based on mass, unless other specified.

The weight average molecular weight is a value measured by a gel permeation chromatography method using polystyrene as the standard substance.

The content of fluorine atoms contained in the fluoropolymer was measured by the following method. That is, a obtained fluororesin was completely burned and decomposed at 1,200° C., and the generated gas was absorbed in 50 g of water. The amount of fluoride ions in the obtained aqueous solution was quantified by a NMR method, and the content of fluorine atoms contained in the fluoropolymer was calculated.

The acid value (mgKOH/g) and the number of ethylenic double bonds per molecule, are theoretical values calculated from the blend proportions of monomers as the raw materials.

The surface charge of particles was measured by a colloidal particle charge analyzing system manufactured by Nippon Rufuto co., Ltd.

Abbreviations of compounds used in the following respective Examples will be shown.

C6FMA: CH₂═C(CH₃)COOCH₂CH₂(CF₂)₆F,

2-HEMA: 2-hydroxyethyl methacrylate,

MAA: methacrylic acid,

IBMA: isobornyl methacrylate,

2-ME: 2-mercaptoethanol,

V-70: 2,2′-azobis(4-methoxy-2,4-dimethylvaleronitrile) (manufactured by Wako Pure Chemical Industries, Ltd., tradename: V-70),

BE1: 1,1-bis(acryloyloxymethyl)ethyl isocyanate (manufactured by Showa Denko K.K., tradename: Karenz BEI),

DBTDL: dibutyltin dilaurate,

BHT: 2,6-di-t-butyl-p-cresol,

ZFR1492H: bisphenol F type epoxy acrylate (manufactured by NIPPON KAYAKU CO., LTD., tradename: ZFR-1492H, solid content: 65 mass %),

ZCR-1571H: biphenyl type epoxy acrylate (manufactured by NIPPON KAYAKU CO., LTD., tradename: ZCR1571H, solid content: 70 mass %),

OXE02: ethanone 1-[9-ethyl-6-(2-methylbenzoyl)-9H-carbazoyl-3-yl]-1-(o-acetyloxime) (manufactured by Ciba Specialty Chemicals K.K., tradename: OXE02),

silica dispersion: propylene glycol monomethyl ether acetate solution of silica (silica content: 15 mass %, average particle size of silica particles: 20 nm, the surface charge of the particles was examined, whereupon they were negatively charged),

zirconia dispersion: propylene glycol monomethyl ether acetate solution of zirconia (zirconia content: 15 mass %, average particles size of zirconia particles: 10 nm, the surface charge of the particles was examined, whereupon they were negatively charged),

D310: dipentaerythritol pentaacrylate (manufactured by NIPPON KAYAKU CO., LTD., tradename: KAYARAD D-310),

KBM403: 3-glycidoxypropyltrimethoxysilane (manufactured by Shin-Etsu Chemical Co., Ltd., tradename: KBM-403),

PGMEA: propylene glycol monomethyl ether acetate,

DEGDM: diethylene glycol dimethyl ether.

### Preparation Example 1

### Preparation of Fluoropolymer (A1)

### (Copolymerization)

Into an autoclave having an internal capacity of 1 L and equipped with a stirrer, acetone (556.0 g), C6FMA (96.0 g), MM (28.8 g), 2-HEMA (96.0 g), a chain transfer agent 2-ME (7.8 g) and a polymerization initiator V-70 (3.6 g) were charged, and polymerized at 40° C. for 18 hours with stirring in a nitrogen atmosphere to obtain a solution of copolymer 1. The weight average molecular weight of copolymer 1 was 5,600.

To the obtained acetone solution of copolymer 1, water was added for reprecipitation for purification, and then reprecipitation for purification was carried out by means of petroleum ether, followed by vacuum drying, to obtain 237 g of copolymer 1.

### (Introduction of Ethylenic Double Bonds)

Into a glass flask having an internal capacity of 500 mL and equipped with a thermometer, a stirrer and a heating device, copolymer 1 (100 g), BEI (76.3 g), DBTDL (0.31 g), BHT (3.8 g) and acetone (100 g) were charged and polymerized at 30° C. for 18 hours with stirring to obtain a solution of fluoropolymer (A1). To the obtained acetone solution of fluoropolymer (A1), water was added for reprecipitation for purification, and then reprecipitation for purification was carried out by means of petroleum ether, followed by vacuum drying to obtain 175 g of fluoropolymer (A1). The weight average molecular weight was 10,500, the fluorine atom content was 11.0%, the number of ethylenic double bonds in one molecule was 16, and the acid value was 30 mgKOH/g.

### Preparation Example 2

### Preparation of comparative polymer (R1)

Into an autoclave having an internal capacity of 1 L and equipped with a stirrer, acetone (556.0 g), C6FMA (115.2 g), MAA (12.0 g), IBMA (112.8 g), a chain transfer agent 2-ME (4.7 g) and a polymerization initiator V-70 (3.1 g) were charged, and polymerized at 40° C. for 18 hours with stirring in a nitrogen atmosphere to obtain a solution of comparative polymer (R1). To the obtained acetone solution of comparative polymer (R1), water was added for reprecipitation for purification, and then reprecipitation for purification was carried out by means of petroleum ether, followed by vacuum drying to obtain 236 g of comparative polymer (R1). The weight average molecular weight was 4,000.

### Example 1 for Preparation of Carbon Black Dispersion

Carbon black (20 g), a polymer dispersing agent having basic functional groups (BYK161 manufactured by BYK-Chemie, amine value: 36 mgKOH/g, 5 g) and a copper phthalocyanine derivative (1 g) were added to PGMEA (74 g), followed by stirring and mixing by a bead mill dispersing machine to obtain carbon black dispersion 1 (average particle size of carbon black particles: 90 nm).

### Example 2 for Preparation of Carbon Black Dispersion

Carbon black (20 g), a polymer dispersing agent having no basic functional group (BYK103, manufactured by BYK-Chemie, 5 g) and a copper phthalocyanine derivative (1 g) were added to PGMEA (74 g), followed by stirring and mixing by a bead mill dispersing machine to prepare a carbon black dispersion, but no dispersion having high dispersion stability could be obtained.

### Examples 1 to 5

### Preparation of Photosensitive Composition

Polymer (A1), comparative polymer (R1), an alkali soluble photosensitive resin (B), a photopolymerization initiator (C), a black pigment (D), a polymer dispersing agent (E) having basic functional groups, fine particles (F) and other components were blended in proportions (parts by mass) as identified in Table 1 to prepare photosensitive compositions 1 to 5.

TABLE 1

| | | Ex. | | | | |
|---|---|---|---|---|---|---|
| | | 1 | 2 | 3 | 4 | 5 |
| Photosensitive composition | | 1 | 2 | 3 | 4 | 5 |
| Fluoropolymer (A) | Fluoropolymer (A1) | 0.16 | 0.16 | 0.16 | 0.16 | — |
| | Comparative | — | — | — | — | 0.16 |
| | polymer (R1) | | | | | |
| Alkali soluble photosensitive | ZFR1492H | 35.8 | — | 30.8 | 40.3 | 35.8 |
| resin (B) | ZFR1571H | — | 35.0 | — | — | — |
| Photopolymerization initiator | OXE02 | 1.7 | 1.9 | 2.2 | 1.9 | 1.7 |
| (C) | | | | | | |
| Black pigment (D) | Carbon black | 92.3 | 103.0 | 111.0 | 94.4 | 92.3 |
| Polymer dispersing agent | dispersion 1 | | | | | |
| (E) | | | | | | |
| Fine particles (F) | Silica dispersion | 33.2 | — | 49.0 | — | 33.2 |
| | Zirconia dispersion | — | 45.0 | — | — | — |
| Radical crosslinking agent | D310 | 10.0 | 10.0 | 10.0 | 11.2 | 10.0 |
| (G) | | | | | | |
| Silane coupling agent (I) | KBM403 | 1.7 | 1.7 | 1.7 | 1.8 | 1.7 |
| Diluting agent | DEGDM | 25.2 | | | 50.2 | 25.2 |
| | PGMEA | — | 25.2 | 25.2 | — | — |

| | | | | | |
|---|---|---|---|---|---|
| Proportion (mass %) of black pigment (D) in the | 30.5 | 31.2 | 34.6 | 31.2 | 30.5 |
| total solid content | | | | | |
| Proportion (mass %) of transparent fine particles | 8.3 | 10.3 | 11.6 | 0 | 8.3 |
| (F) in the total solid content | | | | | |

### Examples 6 to 10

### Formation and Evaluation of Black Matrix

Each of the above prepared photosensitive compositions 1 to 5 was applied on a glass substrate (tradename, AN100 manufactured by Asahi Glass Company, Limited) by a spinner and dried by heating (prebaked) on a hot plate at 10° C. for 2 minutes to form a coating film having a thickness of 2.0 μm.

Then, a mask having a lattice pattern formed (line width: 20 μm, lattice space: 80 μm×400 μm) was placed above the coating film with a gap of 30 μm, followed by irradiation with light from an ultrahigh pressure mercury lamp (100 mJ/cm²). Then, the substrate was subjected to development treatment at 25° C. for 40 seconds by means of a 0.1 mass % tetramethylammonium hydroxide aqueous solution containing a surfactant, and then washed with water. The substrate surface was dried, followed by post-curing at 240° C. for 20 minutes to obtain a glass substrate (1) having a black matrix formed thereon, corresponding to each photosensitive composition. Further, a glass substrate (2) having a coating film cured product formed thereon, corresponding to each photosensitive composition, was obtained in the same manner as above except that exposure was carried out without use of the above mask. With respect to the respective substrates, the liquid repellency, the sensitivity, the developability and the ink jet coating property were measured and evaluated by the following methods. The evaluation results are shown in Table 2.

### (Liquid Repellency)

The liquid repellency was evaluated by the contact angles (degrees) to water and xylene on the surface of a coating film cured product formed on the above glass substrate (2). The contact angle is an angle between the solid surface and the tangent line against the liquid surface at a point where the solid and the liquid are in contact with each other, and it was defined by the angle on the side containing the liquid. The larger the angle, the better the liquid repellency of the coating film.

The contact angle to water being at least 95° was represented by ◯, the same contact angle being at least 90° and less than 95° was represented by Δ, and the same contact angle being less than 90° was represented by x. The contact angle to xylene being at least 400 was represented by ◯, the same contact angle being at least 35° and less than 40° was represented by Δ, and the same contact angle being less than 35° was represented by x.

### (Sensitivity)

The sensitivity was evaluated by the line width of the lines of the black matrix formed on the above glass substrate (1). The broader the obtained line width, the higher the sensitivity.

### (Ink Jet Coating Property)

With respect to the obtained glass substrate (1), heat-curable inks containing the respective pigments of R, G and B colors were injected with regions partitioned by the black matrix, by means of an ink jet apparatus (Nanoprinter 900 manufactured by MICROJET Corporation) to form ink layers thereby to form pixels. The pixel pattern thus obtained was observed by an ultradeep shape measuring microscope (manufactured by KEYENCE CORPORATION) and evaluated as follows.

◯: A pixel pattern free from color mixing or bleeding of inks between adjacent pixels, free from non-uniformity in the thickness of ink layers within pixels, was obtained.

Δ: Non-uniformity in the thickness of the coating film within pixels was observed, although no color mixing or bleeding of inks between pixels was observed.

x: Color mixing or bleeding of inks between pixels was observed.

In Example 9, since no fine particles (F) were added to the photosensitive composition 4 used, no liquid repellency was developed, and the ink jet coating property was poor.

In Example 10, fine particles (F) were added to the photosensitive composition 5 used, and excellent liquid repellency was obtained, but non-uniformity in the thickness of ink layers within pixels was observed. It is considered to be because comparative polymer (R1) used for the photosensitive composition 5 is hardly fixed to the partition walls since it has no ethylenic double bonds.

TABLE 2

| | | Ex. | | | | |
|---|---|---|---|---|---|---|
| | | 6 | 7 | 8 | 9 | 10 |
| Photosensitive | | 1 | 2 | 3 | 4 | 5 |
| composition | | | | | | |
| Liquid | Water | ◯ | ◯ | ◯ | Δ | ◯ |
| repellency | Xylene | ◯ | ◯ | ◯ | X | ◯ |

| | | | | | |
|---|---|---|---|---|---|
| Sensitivity (μm) | 22.3 | 22.1 | 23.1 | 23.4 | 22.4 |
| Ink jet coating property | ◯ | ◯ | ◯ | X | Δ |

### INDUSTRIAL APPLICABILITY

The photosensitive composition of the present invention is suitably used for formation of partition walls for production of a color filter, for a production of an organic EL display device and for production of a circuit board, utilizing an ink jet printing technique, and is thereby industrially useful.

The entire disclosure of Japanese Patent Application No. 2007-115726 filed on Apr. 25, 2007 including specification, claims, drawings and summary is incorporated herein by reference in its entirety.

What is claimed is:

1. A photosensitive composition, which comprises a fluoropolymer (A) having a side chain containing a group represented by the following formula 1 and a side chain containing an ethylenic double bond in one molecule, an alkali soluble photosensitive resin (B), a photopolymerization initiator (C), a black pigment (D), a polymer dispersing agent (E) having basic functional groups, and fine particles (F) other than the black pigment (D):
—CFXR^{f} formula 1
wherein X is a hydrogen atom, a fluorine atom or a trifluoromethyl group, and R^{f} is an alkyl group having at most 20 carbon atom which may have an etheric oxygen atom, at least one of hydrogen atoms of which is substituted by a fluorine atom, or a fluorine atom.

2. The photosensitive composition according to claim 1, wherein the proportions of the respective components in the total solid content of the photosensitive composition are such that the fluoropolymer (A) is from 0.1 to 30 mass %, the alkali soluble photosensitive resin (B) is from 5 to 80 mass %, the photopolymerization initiator (C) is from 0.1 to 50 mass %, the black pigment (D) is from 20 to 50 mass %, and the fine particles (F) other than the black pigment (D) are from 3 to 20 mass %, and the proportion of the polymer dispersing agent (E) is from 5 to 30 mass % based on the black pigment (D).

3. The photosensitive composition according to claim 1, wherein the fine particles (F) are negatively charged.

4. The photosensitive composition according to claim 1, wherein the fluoropolymer (A) has a side chain containing at least two ethylenic double bonds per one side chain.

5. The photosensitive composition according to claim 1, wherein the fluoropolymer (A) further has a side chain containing an acidic group.

6. Partition walls made of a coating film cured product of the photosensitive composition as defined in claim 1.

7. A black matrix comprising the partition walls as defined in claim 6.

8. A process for forming a black matrix, which comprises a step of coating a substrate with the photosensitive composition as defined in claim 1 to form a coating film, a step of drying the coating film, an exposure step, a development step and a postbaking step in this order.

9. A process for forming a color filter, which comprises, after forming a black matrix by the process as defined in claim 8, injecting an ink by an ink jet method within regions partitioned by the black matrix, to form pixels.

10. A process for forming an organic EL display device, which comprises, after forming a black matrix by the process as defined in claim 8, injecting an ink by an ink jet method within regions partitioned by the black matrix, to form pixels.
